(19) United States
(12) Patent Application Publication
(10) Pub. No.: US 2002/0003443 A1
(43) Pub. Date: Jan. 10, 2002

(54) Toggle flip-flop circuit, prescaler, and PLL circuit

(75) Inventor: Morihito Hasegawa, Kasugai-shi (JP)

Correspondence Address: ARENT FOX KINTNER PLOTKIN & KAHN, PLLC, Suite 600, 1050 Connecticut Avenue, N.W., Washington, DC, 20036-5339, US

(73) Assignee: FUJITSU LIMITED

(21) Appl. No.: 09/797,680

(22) Filed: Mar. 5, 2001

(30) Foreign Application Priority Data
Jul. 6, 2000 (JP) 2000-205149

(51) Int. Cl. H03K 3/289

(52) U.S. Cl. 327/202

(57) ABSTRACT

A toggle flip-flop circuit that increases operational speed and decreases power consumption with a simplified configuration. The toggle flip-flop circuit has a master latch circuit, which includes an emitter-coupled logic (ECL) circuit, and a slave latch circuit, which includes an ECL circuit. The master slave circuit and the slave latch circuit are driven by the same ECL drive circuit.

### BACKGROUND OF THE INVENTION

The present invention relates to a toggle flip-flop, and more particularly, to a toggle flip-flop used in a divider, such as a prescaler of a PLL circuit.

Phase-locked loop (PLL) circuits are used in mobile communication devices, such as cellular telephones. To improve the performance of the mobile communication device, a PLL circuit must increase operational speed, enable higher integration, and decrease power consumption.

FIG. 1 is a circuit diagram of a toggle flip-flop (TFF) circuit 50 used in a prescaler of a PLL circuit. The toggle flip-flop circuit 50 includes emitter-coupled logic (ECL) circuits. The toggle flip-flop circuit 50 is provided with a master latch circuit 1, a slave latch circuit 2, ECL drive circuits 3, 4, and transistors Tr1, Tr2.

In response to the rising and falling of clock signals CK, XCK, the master latch circuit 1 alternately acquires output signals OUT, /OUT and latches and outputs the output signals OUT, /OUT.

In response to the rising and falling of the clock signals CK, XCK, the slave latch circuit 2 alternately acquires the output signals of the master latch circuit 1 and latches and outputs the output signals. The slave latch circuit 2 outputs the output signals OUT, /OUT by dividing the clock signals CK, XCK by two in accordance with the clock signals CK, XCK.

The transistors Tr1, Tr2 function as current sources for activating each of the ECL drive circuits 3, 4 in response to an activation signal Vcs.

In the toggle flip-flop circuit 50, the clock signals CK, XCK are provided to the bases of two NPN transistors in each of the ECL drive circuits 3, 4. Thus, signal lines extending from a pair of output terminals of a clock signal supply circuit (not shown) to the base of each transistor are required. This increases line capacitance.

Further, since the bases of the two transistors are connected to each output terminal of the clock signal supply circuit, base capacitance is increased. As a result, the load applied to each output terminal of the clock signal supply circuit is increased.

FIG. 2 is a chart showing simulated waveforms that would result if the toggle flip-flop circuit 50 were supplied with a power of 2.7V and operated based on 1.1 GHz clock signals CK, XCK. As apparent from FIG. 2, the output signals OUT, /OUT are unstable and do not behave properly.

FIG. 3 is a chart showing simulated waveforms that would result if the toggle flip-flop circuit 50 were supplied with a power of 3.0V and operated based on 1.1 GHz clock signals CK, XCK. In this case, the output signals OUT, OUT/ are more stable in comparison to the output signals OUT, OUT/ of FIG. 2. However, the phases of the output signals OUT/, OUT relative to the clock signals CK, XCK are unstable. Thus, the toggle flip-flop circuit 50 does not function as desired.

Accordingly, the toggle flip-flop circuit 50 is not able to operate correspondingly with faster clock signals CK, XCK. Further, the wiring capacitance and base capacitance increases power consumption of the toggle flip-flop circuit 50.

Additionally, the ECL drive circuits 3, 4, which activate the master latch circuit 1 and the slave latch circuit 2, each require two transistors. Two further transistors functioning as current sources that activate the ECL drive circuits 3, 4 are also required. This increases the circuit scale, which in turn, hinders higher integration.

### SUMMARY OF THE INVENTION

It is an object of the present invention to provide a toggle flip-flop that has low power consumption and enables high-speed operation and higher integration.

To achieve the above object, the present invention provides a toggle flip-flop circuit having a master latch circuit including an emitter-coupled logic (ECL) circuit. A slave latch circuit is connected to the master latch circuit. The slave latch circuit includes an ECL circuit. An ECL drive circuit is connected to the master latch circuit and the slave latch circuit. The ECL drive circuit drives both the master slave circuit and the slave latch circuit in accordance with a clock signal.

The present invention also provides a toggle flip-flop circuit having a master latch circuit including a master EtCL section, a slave latch circuit including a slave ECL section, and a common ECL section connected to the master ECL section and the slave ECL section. The common ECL section drives both the first and second ECL sections.

The present invention further provides a prescaler having a frequency division shifting circuit for shifting a frequency division ratio in response to a frequency division ratio shifting signal and dividing an input signal in accordance with the shifted frequency division ratio. An asynchronous extender is connected to the frequency division shifting circuit. The asynchronous extender includes at least one toggle flip-flop circuit. The toggle flip-flop circuit has a master latch circuit including a master ECL section, a slave latch circuit including a slave ECL section, and a common ECL section connected to the master ECL section and the slave ECL section. The common ECL section drives both the first and second ECL sections.

The present invention further provides a phase-locked loop (PLL) circuit having a reference frequency divider for dividing the frequency of a reference clock signal to generate a reference signal, and a phase comparator connected to the reference frequency divider. The phase comparator compares a phase of the reference signal to a phase of a comparison signal to generate a phase comparison signal. A charge pump is connected to the phase comparator to convert the phase comparison signal to a voltage signal. A low-pass filter is connected to the charge pump. The charge pump smoothes the voltage signal to generate a smoothed signal. A voltage-controlled oscillator is connected to the low-pass filter. The voltage-controlled oscillator generates an oscillation output signal having a frequency that is based on the smoothed signal of the low-pass filter. A comparison frequency divider is connected to the voltage-controlled oscillator and the phase comparator. The comparison frequency divider divides the frequency of the oscillation output signal to generate the comparison signal. The comparison frequency divider includes a prescaler for dividing the frequency of the oscillation output signal with a frequency division ratio that is based on a module control signal to generate a prescaler divisional signal. A main counter is connected to the prescaler. The main counter divides the frequency of the prescaler divisional signal to generate the comparison signal. A swallow counter is connected to the prescaler. The swallow counter divides the frequency of the prescaler divisional signal to generate a swallow counter divisional signal. A control circuit is connected to the swallow counter and the main counter. The control circuit generates the module control signal based on the comparison signal and the swallow counter divisional signal. The prescaler includes a frequency division shifting circuit for shifting a frequency division ratio in response to the module control signal and dividing an input signal in accordance with the shifted frequency division ratio. An asynchronous extender is connected to the frequency division shifting circuit. The asynchronous extender includes at least one toggle flip-flop circuit. The toggle flip-flop circuit includes a master latch circuit including a master ECL section, a slave latch circuit including a slave ECL section, and a common ECL section connected to the master ECL section and the slave ECL section. The common ECL section drives both the first and second ECL sections.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a circuit diagram of a prior art toggle flip-flop circuit;

FIG. 2 is a waveform chart illustrating the behavior of the toggle flip-flop circuit of FIG. 1;

FIG. 3 is a waveform chart illustrating the behavior of the toggle flip-flop circuit of FIG. 1;

FIG. 4 is circuit diagram of a toggle flip-flop circuit according to a preferred embodiment of the present invention;

FIG. 5 is a waveform chart illustrating the behavior of the toggle flip-flop circuit of FIG. 4;

FIG. 6 is a waveform chart illustrating the behavior of the toggle flip-flop circuit of FIG. 4;

FIG. 7 is a schematic block diagram of a PLL circuit employing the toggle flip-flop circuit according to the present invention; and

FIG. 8 is a schematic circuit diagram of a prescaler employing the toggle flip-flop circuit according to the present invention.

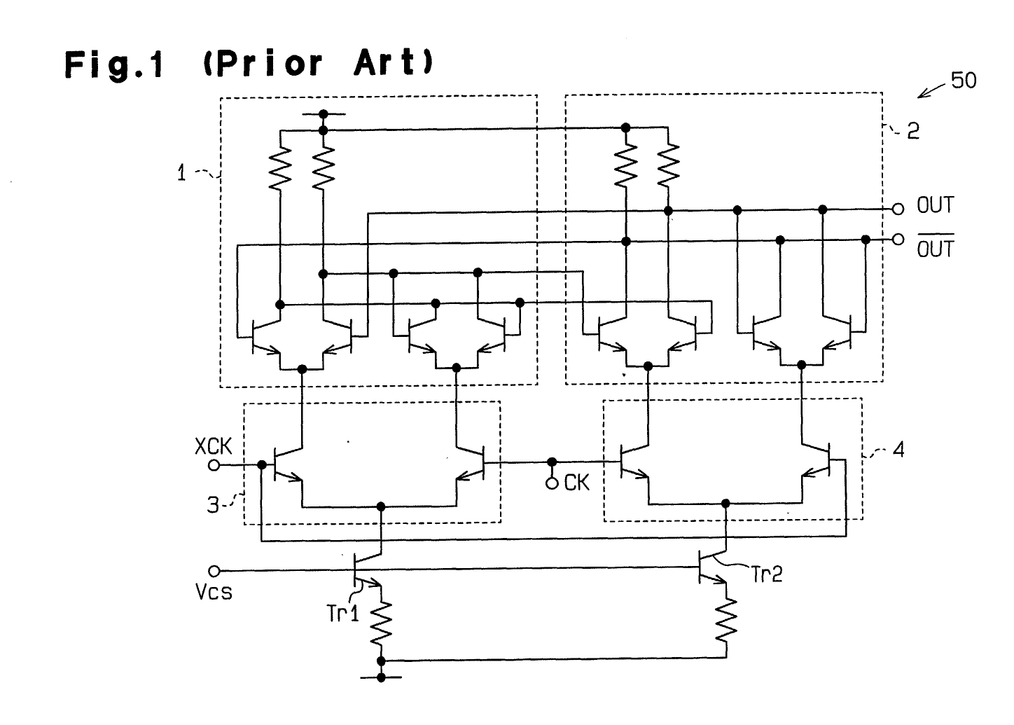

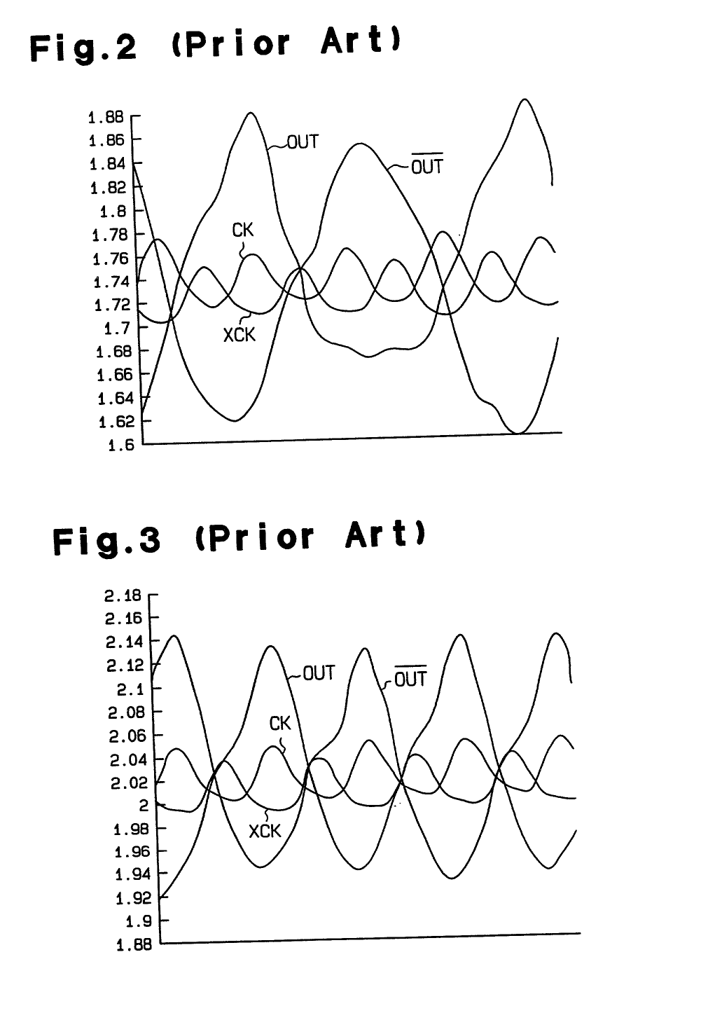

### DETAILED DESCRIPTION OF THE PREFERRED EMBODIMENTS

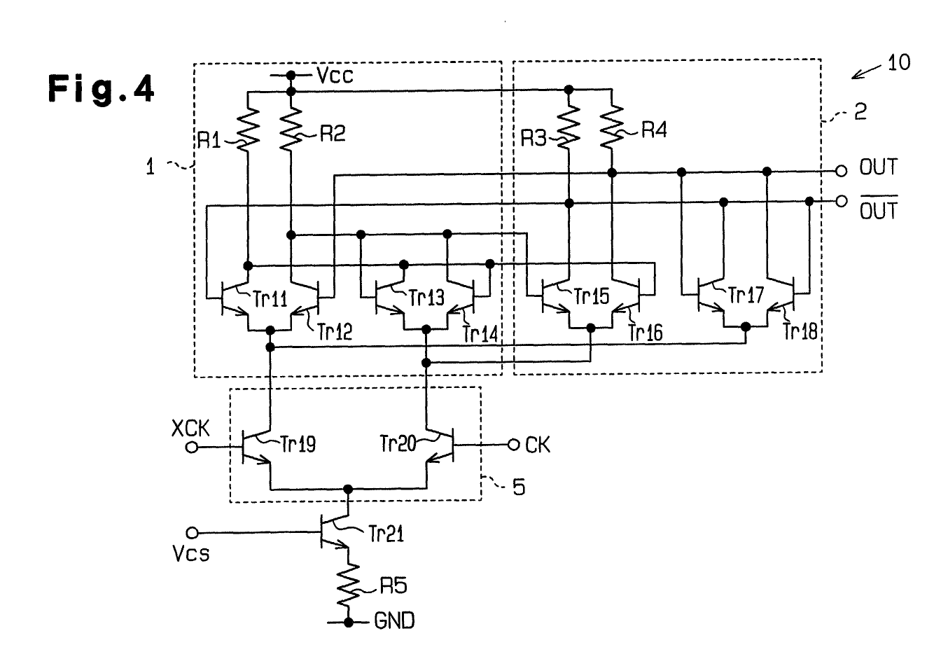

In the drawings, like numerals are used for like elements throughout. FIG. 4 is a circuit diagram of a toggle flip-flop circuit 10 according to a preferred embodiment of the present invention. The toggle flip-flop circuit 10 has a master latch circuit 1, which includes NPN transistors Tr11, Tr12, Tr13, Tr14 and resistors R1, R2. The master latch circuit 1 has a master ECL section, which is configured by a pair of ECL circuits. One of the ECL circuits is formed by the NPN transistors Tr11, Tr12, and the other ECL circuit is formed by the NPN transistors Tr13, Tr14.

The toggle flip-flop circuit 10 also has a slave latch circuit 2, which includes NPN transistors Tr15, Tr16, Tr17, Tr18 and resistors R3, R4. The slave latch circuit 2 has a slave ECL section, which is configured by a pair of ECL circuits. One of the ECL circuits is formed by the NPN transistors Tr15, Tr16, and the other ECL circuit is formed by the NPN transistors Tr17, Tr18.

An ECL drive circuit 5, which includes the transistors Tr19, Tr20, is connected to the master latch circuit 1 and the slave latch circuit 2.

The emitters of the transistors Tr11, Tr12 in the master latch circuit 1 and the emitters of the transistors Tr17, Tr18 in the slave latch circuit 2 are connected to the collector of the transistor Tr19.

The emitters of the transistors Tr13, Tr14 in the master latch circuit 1 and the emitters of the transistors Tr15, Tr16 in the slave latch circuit 2 are connected to the collector of the transistor Tr20.

The emitters of the transistors Tr19, Tr20, which are preferably NPN transistors, are connected to each other. The base of the transistor Tr19 is provided with the clock signal XCK, and the base of the transistor Tr20 is provided with the clock signal CK. The emitters of the transistors Tr19, Tr20 are connected to the collector of the NPN transistor Tr21. The emitter of the transistor Tr21 is connected to the ground GND via a resistor R5. The base of the transistor Tr21 is provided with an activation signal Vcs.

The master latch circuit 1 and the slave latch circuit 2 are set so that their amplitudes are substantially matched.

The transistor Tr21 always activates the ECL drive circuit 5 in response to the activation signal Vcs. The ECL drive circuit 5 drives the master latch circuit 1 and the slave latch circuit 2 based on the clock signals CK, XCK.

In the toggle flip-flop circuit 10, the master latch circuit 1 and the slave latch circuit 2 are driven by the same ECL drive circuit 5. This decreases the line capacitance in comparison with the prior art.

Further the base capacitance of the ECL drive circuit 5 is decreased since the ECL drive circuit 5 is configured by a total of two transistors Tr19, Tr20.

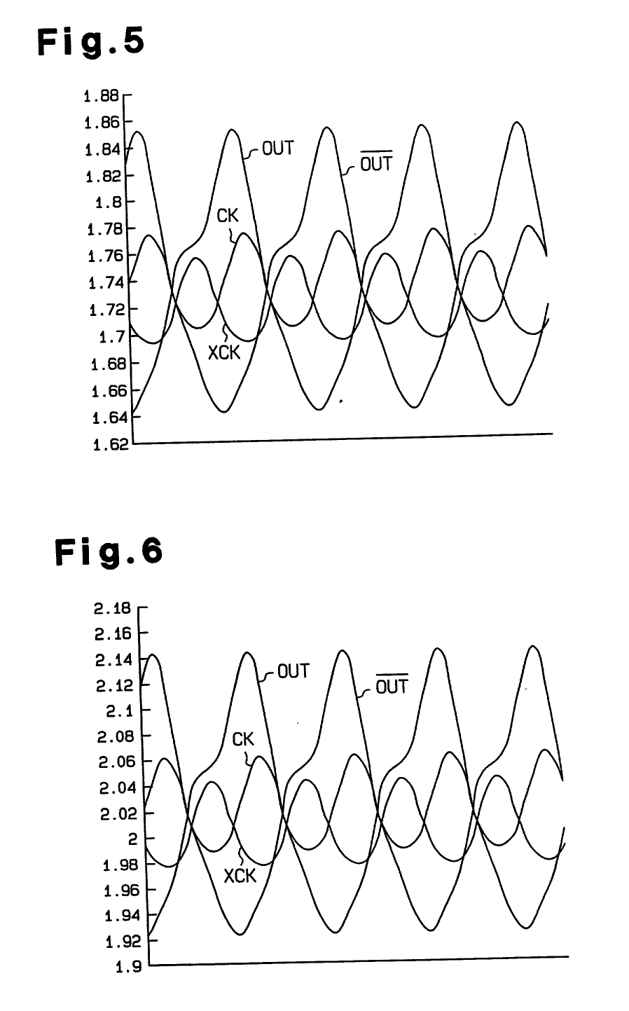

FIG. 5 is a chart showing simulated waveforms that would be obtained when the toggle flip-flop circuit 10 is supplied with a power of 2.7V and operated based on 1.1 GHz clock signals CK, XCK. As apparent from FIG. 5, the output signals OUT, /OUT have stable waveforms and phases that are matched with the phases of the clock signals CK, XCK.

FIG. 6 is a chart showing simulated waveforms that would result if the toggle flip-flop circuit 10 were supplied with a power of 3.0V and operated based on 1.1 GHz clock signals CK, XCK. Like the example shown in FIG. 5, the output signals OUT, /OUT have stable waveforms and have phases that are matched with the phases of the clock signals CK, XCK.

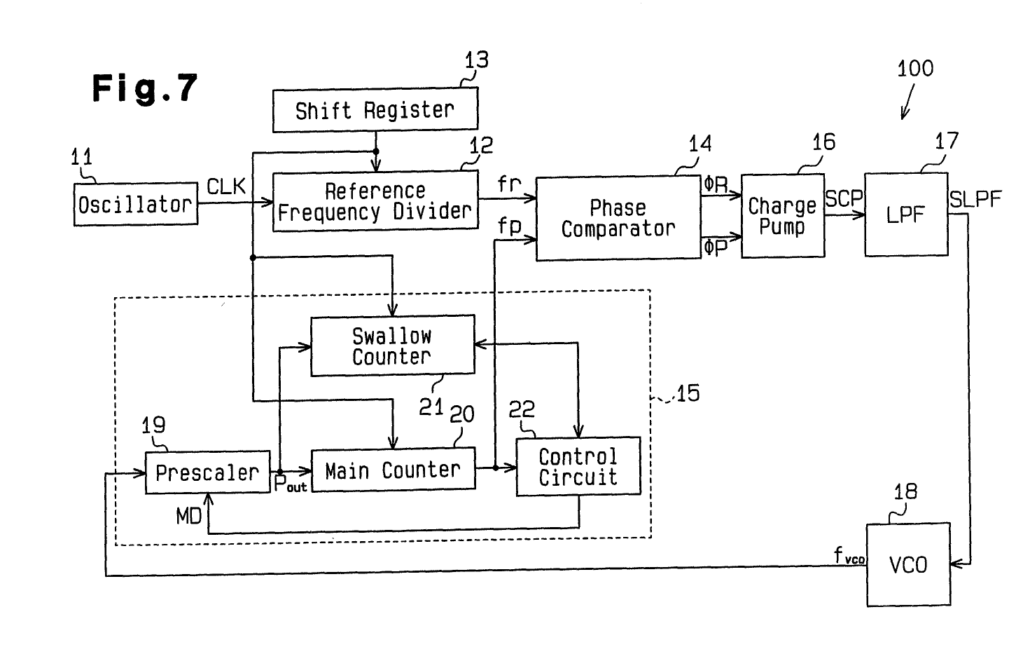

The toggle flip-flop circuit 10 is used in, for example, a prescaler of a PLL circuit. FIG. 7 is a schematic block diagram of a PLL circuit 100, which is provided with a prescaler 19 that includes the toggle flip-flop circuit 10. The PLL circuit 100 includes an oscillator 11, which generates a reference clock signal CLK having an inherent frequency corresponding to the oscillation of a crystal oscillating element. The clock signal CLK is sent to a reference frequency divider 12. The reference frequency divider 12, which includes a counter circuit, divides the frequency of the reference clock signal CLK in accordance with a division ratio determined by a shift register 13 to generate a reference signal fr. The reference signal fr is sent to a phase comparator 14.

The phase comparator 14 receives the reference signal fr from the reference frequency divider 12 and a comparison signal fp from a comparison frequency divider 15. Then, the phase comparator 14 generates pulse signals ΦR, ΦP corresponding to the frequency difference or phase difference between the reference signal fr and the comparison signal fp.

The pulse signals ΦR, ΦP are provided to a charge pump 16 from the phase comparator 14. The charge pump 16 provides an output signal (voltage signal) SCP, which is based on the pulse signals ΦR, ΦP, to a low-pass filter (LPF) 17. The charge pump output signal SCP has direct current components, which include pulse components. The direct current components vary in accordance with the frequency of the pulse signals ΦR, ΦP, and the pulse components vary in accordance with the phase difference between the pulse signals ΦR, ΦP.

The LPF 17 smoothes and eliminates high frequency components from the output signal SCP of the charge pump 16 to generate an output signal SLPF, which is provided to a voltage-controlled oscillator (VCO) 18. The VCO 18 generates an oscillation output signal fvco, which has a frequency corresponding to the voltage value of the output signal SLPF, and provides the oscillation output signal fvco to an external circuit and the comparison frequency divider 15.

The comparison frequency divider 15 is a pulse-swallow type, and includes a prescaler 19, a main counter 20, a swallow counter 21, and a control circuit 22.

The prescaler 19 divides the frequency of the oscillation output signal fvco by M or by (M+1) to generate a prescaler divisional signal Pout. Then, the prescaler 19 provides the prescaler divisional signal Pout to the main counter 20 and the swallow counter 21.

The swallow counter 21 divides the prescaler divisional signal Pout by A and provides a swallow counter divisional signal to the control circuit 22. In accordance with the swallow counter divisional signal, the control circuit 22 provides the prescaler 19 with a module control signal (frequency division ratio shifting signal) MD, which, for example, has a high logic level. When the module control signal MD is high, the prescaler 19 generates the prescaler divisional signal Pout by dividing the oscillation output signal fvco by M.

While the swallow counter 21 is counting an A number of pulses, the control circuit 22 provides the prescaler 19 with, for example, a low module control signal MD. In accordance with the low module control signal MD, the prescaler 19 divides the frequency of the oscillation output signal fvco by (M+1) to generate the prescaler divisional signal Pout.

The shift register 13 determines a division ratio N of the main counter 20. The main counter 20 divides the frequency of the prescaler divisional signal Pout by N to generate the comparison signal fp and provides the comparison signal fp to the phase comparator 14. The divisional signal (comparison signal) fp of the main counter is also provided to the control circuit 22. The control circuit 22 provides the swallow counter 21 with an activation signal each time the main counter 20 divides the frequency of the prescaler divisional signal Pout by N.

Accordingly, whenever the main counter 20 divides the prescaler divisional signal Pout by N, the swallow counter 21 is activated and the prescaler divisional signal Pout is counted.

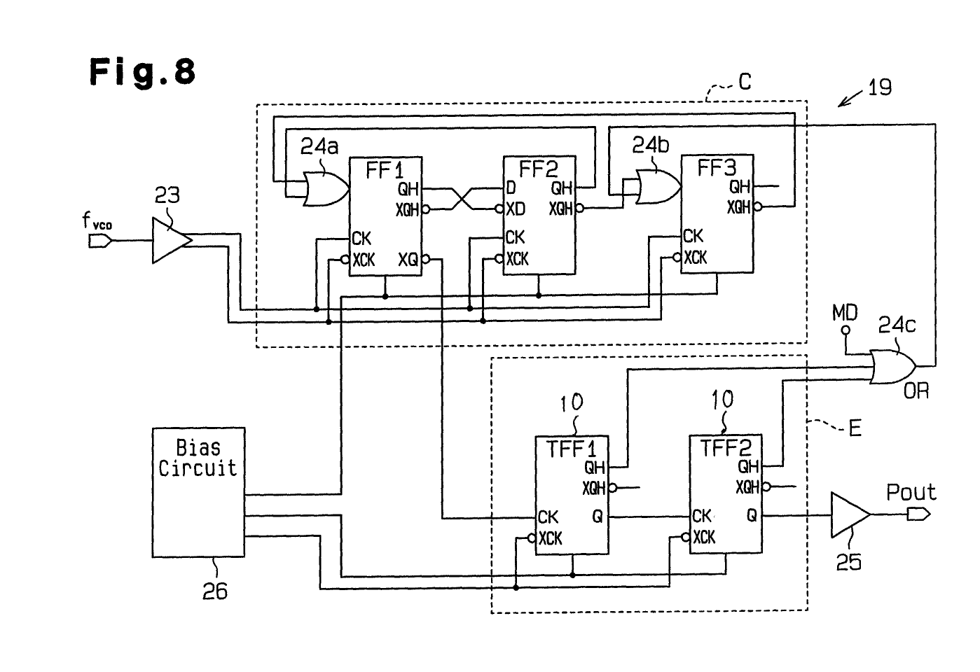

FIG. 8 is a schematic circuit diagram showing the prescaler 19, which includes the toggle flip-flop circuit 10. The oscillation output signal fvco of the VCO 18 is input to synchronous flip-flop circuits FF1, FF2, FF3, which form a frequency division shifting circuit C, as input signals CK, XCK through a buffer circuit 23. It is preferred that each of the flip-flop circuits FF1-FF3 be a D flip-flop (delay flip-flop) circuit.

The flip-flop circuit FF1 provides output signals QH, XQH as data XD, D, respectively, to the flip-flop circuit FF2. The flip-flop circuit FF2 provides its output signal QH to a first input terminal of an OR circuit 24a and its output signal XQH to a first input terminal of an OR circuit 24b.

The OR circuit 24a provides its output signal to the flip-flop circuit FF1. The OR circuit 24b provides its output signal to the flip-flop circuit FF3. The flip-flop circuit FF3 provides its output signal XQH to a second input terminal of the OR circuit 24a.

The frequency division shifting circuit C is connected to an asynchronous extender circuit E, which includes two T-type flip-flop circuits TFF1, TFF2. The flip-flop circuit FF1 provides its output signal XQ as an input signal CK to the flip-flop circuit TFF1 of the asynchronous extender E.

The flip-flop circuit TFF1 provides its output signal Q as an input signal CK to the flip-flop circuit TFF2. The flip-flop circuit TFF2 provides its output signal Q to a buffer circuit 25. The buffer circuit 25 outputs the prescaler divisional signal Pout.

A bias circuit 26 provides the input signal XCK, which has a constant voltage, to the clock terminals of the flip-flop circuits TFF1, TFF2.

The output signals QH of the flip-flop circuits TFF1, TFF2 are respectively provided to first and second input terminals of an OR circuit 24c. A third input terminal of the OR circuit 24c is provided with the module control signal MD. The OR circuit 24c provides its output signal OR to a second input terminal of the bR circuit 24b .

The toggle flip-flop circuit 10 of FIG. 4 is employed as the flip-flop circuits TFF1, TFF2. The output signals OUT, /OUT correspond to the output signals QH, XQH of the flip-flop circuits TFF1, TFF2.

The output signal Q of the flip-flop circuits TFF1, TFF2 is generated by an output transistor (not shown), which functions in accordance with the output signal OUT of the toggle flip-flop circuit 10.

The toggle flip-flop circuit 10, the prescaler 19, and the PLL circuit 100 have the advantages described below.

(1) The master latch circuit 1 and the slave latch circuit 2 are driven by the same ECL drive circuit 5. This decreases the wiring and base capacitances, increases operational speed, and decreases power consumption. In addition, since the number of devices is reduced, higher integration is possible.

(2) The prescaler 19, which includes the toggle flip-flop circuit 10, enables higher operational speed, lower power consumption, and higher integration.

(3) The PLL circuit 100, which includes the prescaler 19, enables higher operational speed, lower power consumption, and higher integration.

It should be apparent to those skilled in the art that the present invention may be embodied in many other specific forms without departing from the spirit or scope of the invention. Particularly, it should be understood that the present invention may be embodied in the following forms.

The transistors of each ECL circuit may be n-channel MOS transistors instead of NPN transistors.

The present examples and embodiments are to be considered as illustrative and not restrictive, and the invention is not to be limited to the details given herein, but may be modified within the scope and equivalence of the appended claims.

What is claimed is:

1. A toggle flip-flop circuit comprising:
a master latch circuit including an emitter-coupled logic (ECL) circuit;
a slave latch circuit connected to the master latch circuit, wherein the slave latch circuit includes an ECL circuit; and
an ECL drive circuit connected to the master latch circuit and the slave latch circuit, wherein the ECL drive circuit drives both the master slave circuit and the slave latch circuit in accordance with a clock signal.

2. The toggle flip-flop circuit according to claim 1, wherein the master latch circuit and the slave latch circuit generate output signals having substantially the same amplitude.

3. A toggle flip-flop circuit comprising:
a master latch circuit including a master ECL section;
a slave latch circuit including a slave ECL section; and
a common ECL section connected to the master ECL section and the slave ECL section, wherein the common ECL section drives both the first and second ECL sections.

4. The toggle flip-flop circuit according to claim 3, wherein the master and slave ECL sections each include a pair of ECL circuits, and the common ECL section includes an ECL circuit.

5. The toggle flip-flop circuit according to claim 4, wherein each of the ECL circuits includes a pair of NPN transistors.

6. The toggle flip-flop circuit according to claim 4, wherein each of the ECL circuits includes a pair of N-channel MOS transistors.

7. A prescaler comprising:
a frequency division shifting circuit for shifting a frequency division ratio in response to a frequency division ratio shifting signal and dividing an input signal in accordance with the shifted frequency division ratio; and
an asynchronous extender connected to the frequency division shifting circuit, wherein the asynchronous extender includes at least one toggle flip-flop circuit, the toggle flip-flop circuit including:
a master latch circuit including a master ECL section;
a slave latch circuit including a slave ECL section; and
a common ECL section connected to the master ECL section and the slave ECL section, wherein the common ECL section drives both the first and second ECL sections.

8. A phase-locked loop (PLL) circuit comprising:
a reference frequency divider for dividing the frequency of a reference clock signal to generate a reference signal;
a phase comparator connected to the reference frequency divider, wherein the phase comparator compares a phase of the reference signal to a phase of a comparison signal to generate a phase comparison signal;
a charge pump connected to the phase comparator to convert the phase comparison signal to a voltage signal;
a low-pass filter connected to the charge pump, wherein the charge pump smoothes the voltage signal to generate a smoothed signal;
a voltage-controlled oscillator connected to the low-pass filter, wherein the voltage-controlled oscillator generates an oscillation output signal having a frequency that is based on the smoothed signal of the low-pass filter; and
a comparison frequency divider connected to the voltage-controlled oscillator and the phase comparator, wherein the comparison frequency divider divides the frequency of the oscillation output signal to generate the comparison signal, wherein the comparison frequency divider includes:
a prescaler for dividing the frequency of the oscillation output signal with a frequency division ratio that is based on a module control signal to generate a prescaler divisional signal;
a main counter connected to the prescaler, wherein the main counter divides the frequency of the prescaler divisional signal to generate the comparison signal;
a swallow counter connected to the prescaler, wherein the swallow counter divides the frequency of the prescaler divisional signal to generate a swallow counter divisional signal; and
a control circuit connected to the swallow counter and the main counter, wherein the control circuit generates the module control signal based on the comparison signal and the swallow counter divisional signal, wherein the prescaler includes:
a frequency division shifting circuit for shifting a frequency division ratio in response to the module control signal and dividing an input signal in accordance with the shifted frequency division ratio; and
an asynchronous extender connected to the frequency division shifting circuit, wherein the asynchronous extender includes at least one toggle flip-flop circuit, wherein the toggle flip-flop circuit includes:
a master latch circuit including a master ECL section;
a slave latch circuit including a slave ECL section; and
a common ECL section connected to the master ECL section and the slave ECL section, wherein the common ECL section drives both the first and second ECL sections.
